(19) United States
(12) Patent Application Publication
(10) Pub. No.: US 2025/0218920 A1
(43) Pub. Date: Jul. 3, 2025

(54) APPARATUS FORMED FROM ELECTRONIC COMPONENTS HAVING DIFFERENT RESPECTIVE THICKNESSES AND METHODS OF FORMING AN APPARATUS FROM ELECTRONIC COMPONENTS HAVING DIFFERENT RESPECTIVE THICKNESSES

(71) Applicant: Microchip Technology Incorporated, Chandler, AZ (US)

(72) Inventor: Mankit Lam, Colorado Springs, CO (US)

(21) Appl. No.: 18/740,864

(22) Filed: Jun. 12, 2024

Related U.S. Application Data
(60) Provisional application No. 63/617,369, filed on Jan. 3, 2024.

(51) Int. Cl. H01L 23/498; H01L 21/48; H01L 23/00; H01L 23/31

(52) U.S. Cl. CPC H01L 23/49861; H01L 21/4853; H01L 23/3107; H01L 23/49838; H01L 24/32; H01L 2224/32245

(57) ABSTRACT

An apparatus includes a pair of substrates with conductive material formed on portions of inwardly facing surfaces thereof, and a step formed in or on the conductive material on one of the pair of substrates. A lead frame having leads and electronic components having different respective thicknesses are mounted between the conductive materials on the pair of substrates. The step has a step thickness dimensioned to facilitate electrical contact between a thickest one of the electronic components or the leads with the step in the conductive material on one of the pair of substrates and the conductive material on the one other of the pair of substrates. An electrical signal path is formed between the electronic components or the leads disposed in electrical contact with the step and the conductive material on the one other of the pair of substrates.

### CROSS-REFERENCE TO RELATED APPLICATION

This application claims the benefit under 35 U.S.C. § 119 (c) of U.S. Provisional Patent Application Ser. No. 63/617,369, filed Jan. 3, 2024, the disclosure of which is hereby incorporated herein in its entirety by this reference.

### FIELD

Examples relate to an apparatus formed from electronic components (e.g., transistors, capacitors, inductors, diodes, resistors, thermistors, without limitation) having different respective thicknesses, such as, an apparatus formed from field-effect transistors, including silicon carbide metal-oxide-semiconductor field-effect transistors, having different respective thicknesses. Other examples relate to methods of forming an apparatus from electronic components having different respective thicknesses.

### BACKGROUND

Packages for electronic components typically include one or more electronic components encased in a molding material and having leads extending therefrom for electrical connection to other, external electronic components. Heat is generated during operation of many electronic components, and packages for electronic components typically provide for dissipation of the heat generated during operation.

Packages for electronic components are formed from any of a number of non-uniform electronic components which often have different configurations, dimensions (e.g., lengths, widths, thicknesses), connection points, as well as different functions. As such, a variety of spacers and wire bond electrical connections are commonly employed to facilitate combining electronic components having different dimensions (e.g., different thicknesses) within a single package. Of course, employing spacers and wire bond electrical connections on upper or lower substrates involves additional handling and requires precision (e.g., individual) placement, which necessarily results in increased manufacturing costs.

### BRIEF SUMMARY

In some examples, an apparatus includes a pair of substrates with a conductive material formed on portions of respective inwardly facing surfaces of insulative materials of the pair of substrates and a step formed in or on the conductive material on one of the pair of substrates. A lead frame having leads, with portions of the leads mounted between the conductive materials on the pair of substrates. Electronic components having different respective thicknesses are mounted between the conductive materials on the pair of substrates, one of the electronic components being thicker or thinner than one other of the electronic components or the leads of the lead frame, or the leads being thicker or thinner than one of the electronic components. The step having a step thickness dimensioned to facilitate electrical contact between a thickest one of the electronic components or the leads of the lead frame with the step formed in or on the conductive material on the one of the pair of substrates and the conductive material on the one other of the pair of substrates, and an electrical signal path between the electronic components having different respective thicknesses or the leads of the lead frame disposed in electrical contact with the step formed in or on the conductive material on the one of the pair of substrates and the conductive material on the one other of the pair of substrates.

In other examples, a method includes forming conductive materials on portions of inwardly facing surfaces of insulative materials of respective ones of a pair of substrates; forming an opening through one of the pair of substrates; forming a step in or on the conductive material on one of the pair of substrates; mounting a lead frame having leads between the conductive materials on the pair of substrates; mounting electronic components having different respective thicknesses between the conductive materials on the pair of substrates; forming an electrical signal path between one of the electronic components having different respective thicknesses or one of the leads of the lead frame and the step in the conductive material on the one of the pair of substrates and the conductive material on the one other of the pair of substrates; and, adding an insulative fill material through the opening to occupy interstices between the pair of substrates.

In further examples, an apparatus includes a first substrate having a first insulative material with a first inwardly facing surface and a first inner conductive material formed on a portion of the first inwardly facing surface, and a second substrate having a second insulative material with a second inwardly facing surface and a second inner conductive material formed on a portion of the second inwardly facing surface. A lead frame having leads is mounted between the first substrate and the second substrate, the lead frame having an extended input/output lead extending continuously between opposing sidewalls of the first substrate and the second substrate. Electronic components having different respective thicknesses are also mounted between the first substrate and the second substrate. A step formed in or on the first inner conductive material overlying the portion of the first inwardly facing surface of the first substrate, the step having a step thickness dimensioned to facilitate electrical contact between a thickest one of the electronic components having different respective thicknesses or of the leads of the lead frame with the step formed in or on the conductive material on the one of the pair of substrates and the conductive material on the one other of the pair of substrates. The apparatus includes a heat dissipating outer conductive material formed on a portion of an outwardly facing surface of the first insulative material of the first substrate or the second insulative material of the second substrate.

### BRIEF DESCRIPTION OF THE DRAWINGS

While this disclosure concludes with claims particularly pointing out and distinctly claiming specific examples, various features and advantages of examples within the scope of this disclosure may be more readily ascertained from the following description when read in conjunction with the accompanying drawings. In the drawings:

FIG. 1 presents a cross-sectional view of an example of an apparatus formed from electronic components having different respective thicknesses, in accordance with examples of the disclosure;

FIG. 2 presents a partially exploded view of the apparatus formed from electronic components having different respective thicknesses of FIG. 1, in accordance with examples of the disclosure;

FIGS. 3A and 3B present top plan and elevation views, respectively, of one substrate of an apparatus formed from electronic components having different respective thicknesses, in accordance with examples of the disclosure;

FIGS. 4B and 4B present top plan and elevation views, respectively, of one other substrate of an apparatus formed from electronic components having different respective thicknesses, in accordance with examples of the disclosure;

FIG. 5 presents bottom plan, side elevation, and top plan views of examples of electronic components having different respective thicknesses such as may be incorporated into an apparatus formed from electronic components having different respective thicknesses, in accordance with examples of the disclosure;

FIG. 6 presents a top plan view of a lead frame of an apparatus formed from electronic components having different respective thicknesses, in accordance with examples of the disclosure;

FIG. 7 presents a top plan view of an apparatus formed from electronic components having different respective thicknesses with some features removed for purposes of clarity, in accordance with examples of the disclosure;

FIG. 8 presents a top plan view of the apparatus formed from electronic components having different respective thicknesses of FIG. 7 showing additional features, in accordance with examples of the disclosure;

FIG. 9 presents a top plan view of the assembled apparatus formed from electronic components having different respective thicknesses of FIGS. 7 and 8, in accordance with examples of the disclosure;

FIG. 10 presents a cross-sectional view of an example of an apparatus formed from electronic components having different respective thicknesses, in accordance with examples of the disclosure;

FIG. 11 presents a partially exploded view of the apparatus formed from electronic components having different respective thicknesses of FIG. 10, in accordance with examples of the disclosure;

FIG. 12 presents a cross-sectional view of an example of an apparatus formed from electronic components having different respective thicknesses, in accordance with examples of the disclosure; and

FIG. 13 presents a flowchart of one example of a method of forming an apparatus from electronic components having different respective thicknesses, in accordance with examples of the disclosure.

### DETAILED DESCRIPTION

The illustrations presented in this disclosure are not meant to be actual views of any apparatus formed from electronic components having different respective thicknesses, or components thereof, but are merely idealized representations employed to describe illustrative examples. Thus, the drawings are not necessarily to scale.

As used herein, the term “about,” when either is used in reference to a numerical value for a particular parameter, are inclusive of the numerical value and a degree of variance from the numerical value that one of ordinary skill in the art would understand is within acceptable tolerances for the particular parameter. For example, “about,” in reference to a numerical value, may include additional numerical values within a range of from 90.0 percent to 110.0 percent of the numerical value, such as within a range of from 95.0 percent to 105.0 percent of the numerical value, within a range of from 97.5 percent to 102.5 percent of the numerical value, within a range of from 99.0 percent to 101.0 percent of the numerical value, within a range of from 99.5 percent to 100.5 percent of the numerical value, or within a range of from 99.9 percent to 100.1 percent of the numerical value.

As used herein, the term “substantially,” when referring to a parameter, property, or condition, means and includes the parameter, property, or condition being equal to or within a degree of variance from a given value such that one of ordinary skill in the art would understand such given value to be acceptably met, such as within acceptable manufacturing tolerances. By way of example, depending on the particular parameter, property, or condition that is substantially met, the parameter, property, or condition may be “substantially” a given value when the value is at least 90.0 percent met, at least 95.0 percent met, at least 99.0 percent met, or even at least 99.9 percent met.

As used in the present disclosure, the term “combination” with reference to a plurality of elements may include a combination of all the elements or any of various different subcombinations of some of the elements. For example, the phrase “A, B, C, D, or combinations thereof” may refer to any one of A, B, C, or D; the combination of A, B, C, and D; and any subcombination of A, B, C, or D such as A, B, and C; A, B, and D; A, C, and D; B, C, and D; A and B; A and C; A and D; B and C; B and D; or C and D.

Terms used in the present disclosure and especially in the appended claims (e.g., bodies of the appended claims, without limitation) are generally intended as “open” terms (e.g., the term “including” should be interpreted as “including, but not limited to,” the term “having” should be interpreted as “having at least,” the term “includes” should be interpreted as “includes, but is not limited to,” without limitation).

Additionally, if a specific number of an introduced claim recitation is intended, such an intent will be explicitly recited in the claim, and in the absence of such recitation no such intent is present. For example, as an aid to understanding, the following appended claims may contain usage of the introductory phrases “at least one” and “one or more” to introduce claim recitations. However, the use of such phrases should not be construed to imply that the introduction of a claim recitation by the indefinite articles “a” or “an” limits any particular claim containing such introduced claim recitation to examples containing only one such recitation, even when the same claim includes the introductory phrases “one or more” or “at least one” and indefinite articles such as “a” or “an” (e.g., “a” and/or “an” should be interpreted to mean “at least one” or “one or more,” without limitation); the same holds true for the use of definite articles used to introduce claim recitations.

In addition, even if a specific number of an introduced claim recitation is explicitly recited, those skilled in the art will recognize that such recitation should be interpreted to mean at least the recited number (e.g., the bare recitation of “two recitations,” without other modifiers, means at least two recitations, or two or more recitations, without limitation). Furthermore, in those instances where a convention analogous to “at least one of A, B, and C, without limitation” or “one or more of A, B, and C, without limitation” is used, in general such a construction is intended to include A alone, B alone, C alone, A and B together, A and C together, B and C together, or A, B, and C together, without limitation.

Further, any disjunctive word or phrase presenting two or more alternative terms, whether in the description, claims, or drawings, should be understood to contemplate the possibilities of including one of the terms, either of the terms, or both terms. For example, the phrase “A or B” should be understood to include the possibilities of “A” or “B” or “A and B.”

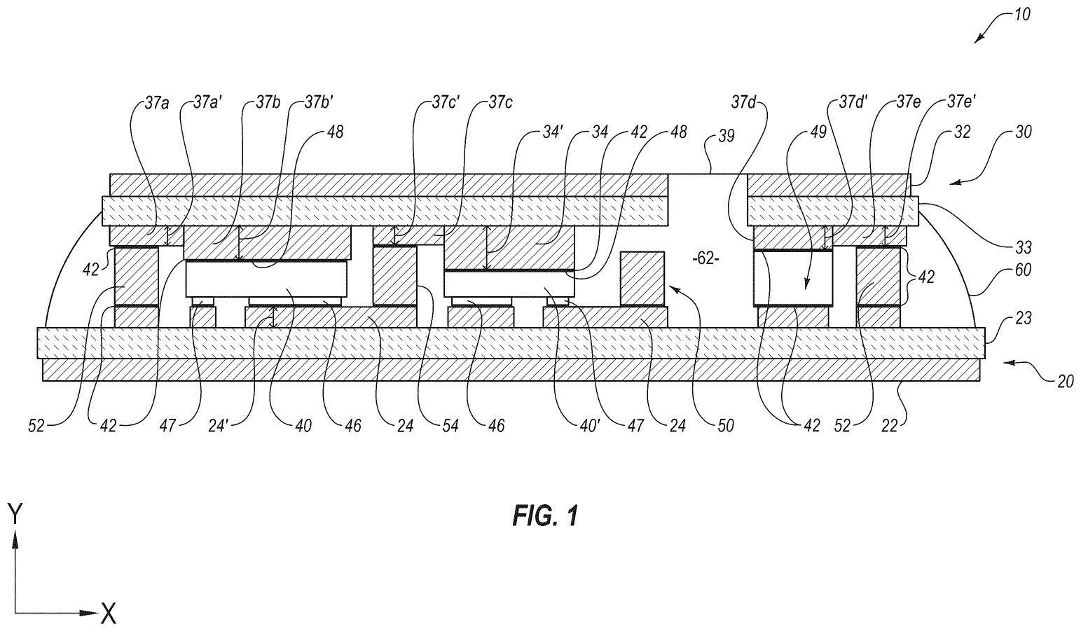

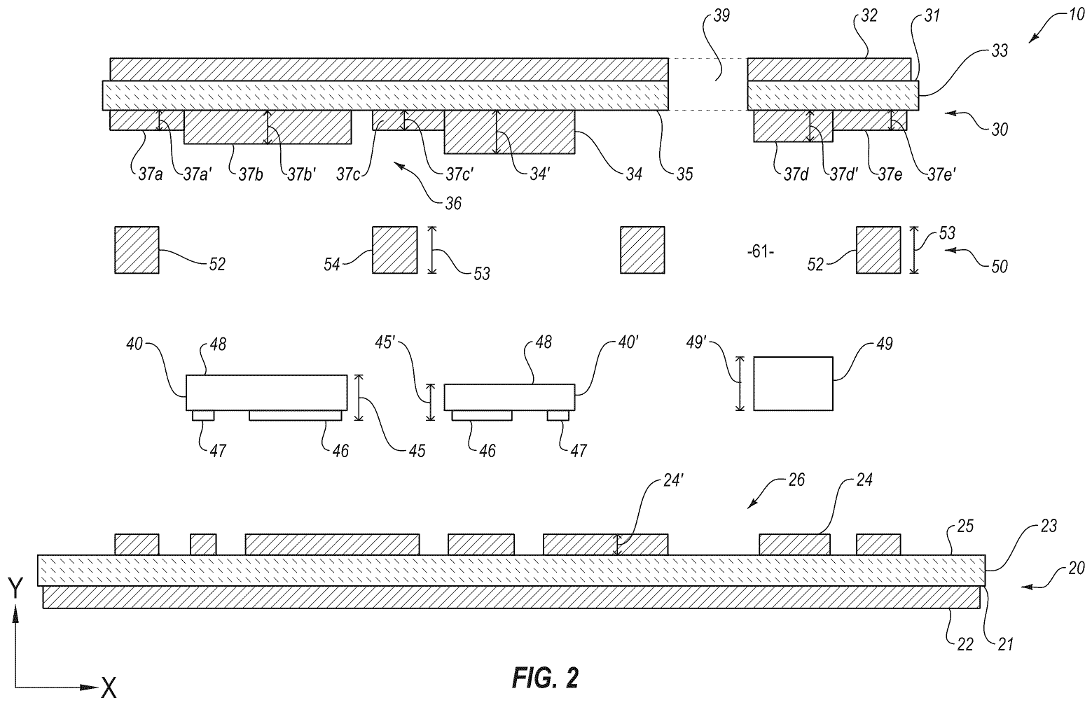

FIG. 1 presents a cross-sectional view of one example of an apparatus 10 an apparatus formed of electronic components having different respective thicknesses, without limitation, and FIG. 2 presents a partially exploded view thereof, in accordance with examples of the disclosure. As shown in FIGS. 1 and 2, the apparatus 10 includes a first substrate 20 (which may be alternatively termed one substrate, or lower substrate) and a second substrate 30 (which may be alternatively termed one other substrate, or upper substrate). The first substrate 20 or the second substrate 30 may respectively include a direct bonded copper (DBC) substrate or an active metal brazed (AMB) substrate. In some examples, the first substrate 20 and the second substrate 30, whether a DBC substrate, an AMB substrate, or other, include a first insulative material 23 and a second insulative material 33, respectively. The first and second insulative materials 23, 33 may be electrically insulative, thermally insulative, or both (e.g., ceramic, engineered ceramic, without limitation). The first and second insulative materials 23, 33 may respectively have a thickness in a range of from about 0.100 millimeters (mm) to about 1.000 mm.

The first substrate 20 and the second substrate 30 include respective inner conductive materials 24, 34 formed on portions of respective inwardly facing surfaces 25, 35 of the first and second insulative materials 23, 33 thereof, respectively. Specifically, the first substrate 20 includes a first inner conductive material 24 formed on a portion of a first inwardly facing surface 25 of the first insulative material 23 of the first substrate 20, and the second substrate 30 includes a second inner conductive material 34 formed on a portion of a second inwardly facing surface 35 of the second insulative material 33 of the second substrate 30, as shown in FIGS. 1 and 2. The first and second inner conductive materials 24, 34 may include any of a number of conductive materials which may be electrically conductive, thermally conductive, or both, without limitation (e.g., metals, metal alloys, or combinations thereof, without limitation). The first and second inner conductive materials 24, 34 may have a thickness 24′, 34′, respectively, in a range of from about 0.200 mm to about 1.000 mm.

The first substrate 20 and the second substrate 30 may also include respective outer conductive materials 22, 32 formed on portions of respective outwardly facing surfaces 21, 31 of the first and second insulative materials 23, 33 thereof, respectively. More particularly, the first substrate 20 may include a first outer conductive material 22 formed on a portion of a first outwardly facing surface 21 of the first insulative material 23 of the first substrate 20, and the second substrate 30 may include a second outer conductive material 32 formed on a portion of a second outwardly facing surface 31 of the second insulative material 33 of the second substrate 30, as also shown in FIGS. 1 and 2. Similar to the first and second inner conductive materials 24, 34, respectively, the first outer conductive material 22 and the second outer conductive material 32 may include any of a number of conductive materials which may be electrically conductive, thermally conductive, or both, without limitation (e.g., metals, metal alloys, or combinations thereof, without limitation). The first and second outer conductive material 22, 32 may respectively have thicknesses in a range of from about 0.200 mm to about 1.000 mm. The first or second outer conductive materials 22, 32 may comprise the same conductive materials as respective first or second inner conductive materials 24, 34, or the first or second outer conductive materials 22, 32 may comprise different conductive materials than the respective first or second inner conductive materials 24, 34. In some examples, the first and second outer conductive materials 22, 32 act to dissipate heat (e.g., heat dissipating outer conductive materials, without limitation) during operation of the apparatus 10.

In some examples, the first insulative material 23 of the first substrate 20 includes silicon nitride (Si₃N₄) having a thickness of from about 0.25 mm to about 0.32 mm, the first inner conductive material 24 includes copper (Cu) having a thickness 24′ of about 0.208 mm, and the first outer conductive material 22 includes copper (Cu) and having a thickness of about 0.208 mm. In some other examples, the second insulative material 33 of the second substrate 30 includes silicon nitride (Si₃N₄) having a thickness of from about 0.25 mm to about 0.32 mm, the second inner conductive material 34 includes copper (Cu) having a thickness 34′ of about 0.508 mm, and the second outer conductive material 32 includes copper (Cu) and having a thickness of about 0.208 mm.

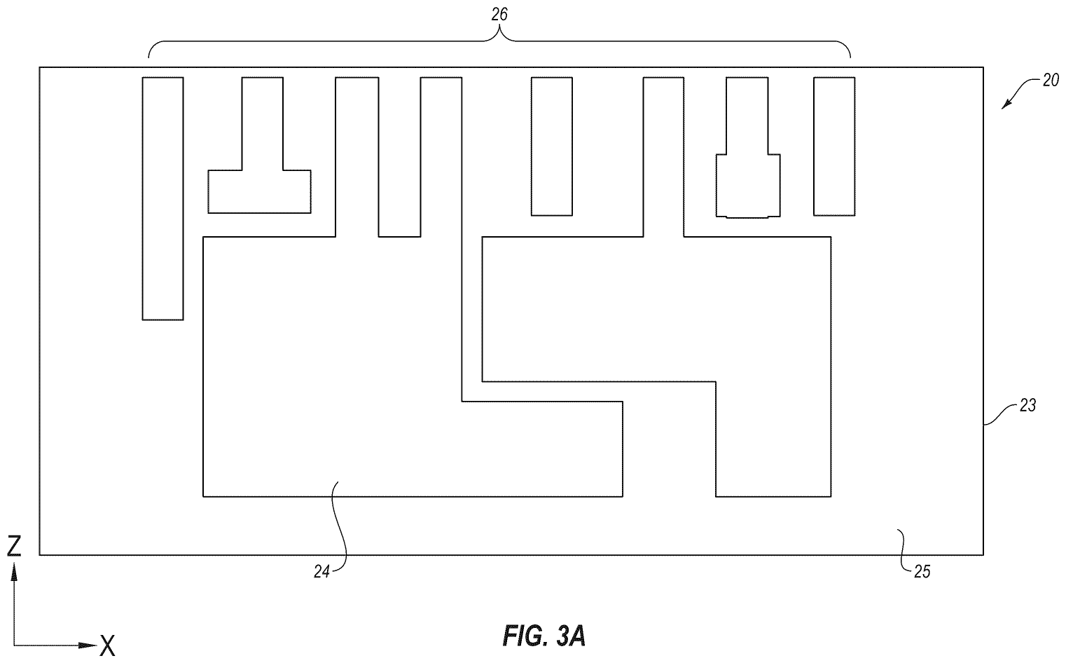

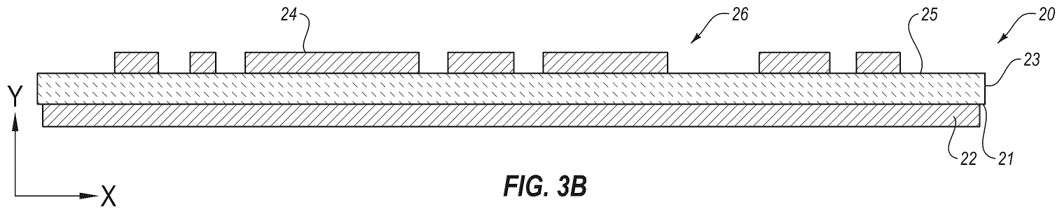

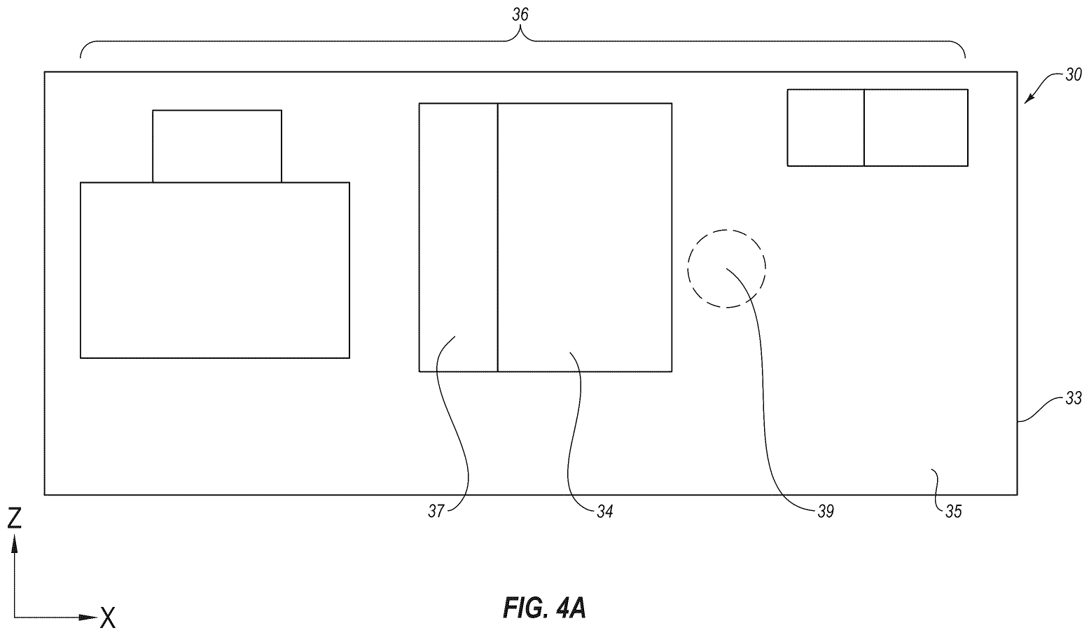

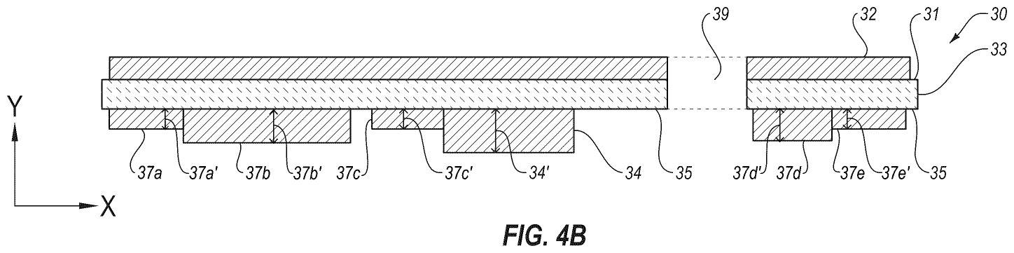

FIGS. 3A and 3B present top plan and elevation views, respectively, of first substrate 20, and FIGS. 4A and 4B present top plan and elevation views, respectively, of second substrate 30, in accordance with examples of the disclosure. In some examples, portions of the first and second inner conductive materials 24, 34 are removed from the respective first and second substrates 20, 30, thereby exposing the underlying insulative materials 23, 33, respectively. As shown in FIGS. 3A and 3B, a first circuit pattern 26 is formed by the portions of the first inner conductive material 24 remaining on the underlying first insulative material 23 of the first substrate 20. The first circuit pattern 26 partially defines the locations for mounting, in accordance with some examples, electronic components 40, 40′, thermistor 49 (e.g., electronic components having different respective thicknesses, without limitation), and leads 52, 54 of lead frame 50 (see FIG. 2), as described hereinafter and which may have different respective thicknesses, to the first inner conductive material 24 of the first substrate 20. With reference next to FIGS. 4A and 4B, a second circuit pattern 36 is formed by the portions of the second inner conductive material 34 remaining on the underlying second insulative material 33 of the second substrate 30. The second circuit pattern 36 likewise partially defines the locations for mounting, in accordance with some examples, electronic components 40, 40′, thermistor 49 (e.g., electronic components having different respective thicknesses, without limitation), and leads 52, 54 of lead frame 50, to the second inner conductive material 34 of the second substrate 30.

One of the first substrate 20 or the second substrate 30 may include a step 27, 37 (e.g., step 27, 37a-37o) formed in or on the first inner conductive material 24 or the second inner conductive material 34, respectively. Step 27, 37 has a step thickness 27′, 37′ (e.g., step thickness 27′, 37a′-37o′) which is less than the thickness 24′, 34′ of the respective first inner conductive material 24 or second inner conductive material 34 in or on which the step 27, 37 is formed. In some examples, the first substrate 20 and the second substrate 30 include a step 27, 37 formed in or on the first and second inner conductive materials 24, 34, respectively. In other examples, the first substrate 20 or the second substrate 30 may include a number of steps 27, 37 (e.g., steps 27, 37a-37o) formed in or on the first inner conductive material 24 or the second inner conductive material 34, respectively.

In some examples, a respective step 27, 37 (e.g., step 27, 37a-37o) is formed in the first or second inner conductive materials 24, 34 by selectively removing portions of the first or second inner conductive materials 24, 34, thereby reducing the thickness 24′, 34′ of the first or second inner conductive materials 24, 34, respectively, and forming the step 27, 37 in the first or second inner conductive materials 24, 34, respectively, where portions of the first or second inner conductive materials 24, 34 were removed (e.g., forming steps by a subtractive process). A step 27, 37 formed by a subtractive process comprises the same material of construction as the respective one of the first inner conductive material 24 or the second inner conductive material 34 in which it is formed. As one example, the second inner conductive material 34 of the second substrate 30 has a thickness 34′ (e.g., about 0.508 mm), and a step 37 (e.g., step 37a-37o) is formed in the second inner conductive material 34, by selectively removing portions (e.g., removing about 0.300 mm) of the second inner conductive material 34 on the second substrate 30, such that the step 37 formed in the second inner conductive material 34 has a step thickness 37′ (e.g., about 0.208 mm). Thus, in accordance with this example, about 0.300 mm of the thickness 34′ of about 0.508 mm of the second inner conductive material 34 is removed to form the step 37 having a step thickness 37′ of about 0.208 mm.

In other examples, a step 27, 37 (e.g., step 27, 37a-37o) is formed on the first or second inner conductive materials 24, 34 by selectively adding material onto portions of the first or second inner conductive materials 24, 34, thereby increasing the thickness 24′, 34′ of the first or second inner conductive materials 24, 34, respectively, and forming the step 27, 37 on the portions of the first or second inner conductive materials 24, 34, respectively, where material was not added (i.e., forming steps by an additive process). In some examples, the material added onto portions of the first or second inner conductive materials 24, 34 to form step 27, 37 (e.g., step 27, 37a-37o) by an additive process comprises the same material of construction as the respective one of the first inner conductive material 24 or the second inner conductive material 34 on which the step 27, 37 is formed. In some other examples, the material added onto portions of the first or second inner conductive materials 24, 34 to form step 27, 37 by an additive process comprises a material of construction (e.g., a conductive material) which is different than the material of construction of the respective one of the first inner conductive material 24 or the second inner conductive material 34 on which the step 27, 37 is formed.

The steps 27, 37 (e.g., steps 27, 37a-37o) in the first inner conductive material 24 or the second inner conductive material 34 of the first substrate 20 or the second substrate 30, respectively, eliminate the need for spacers being positioned between the first substrate 20 and the second substrate 30 to accommodate different dimensions (e.g., different respective thicknesses, without limitation) of the electronic components 40, 40′, thermistor 49 (e.g., electronic components having different respective thicknesses, without limitation), and leads 52, 54 of lead frame 50, mounted therebetween, thereby eliminating the additional (e.g., individualized, without limitation) handling and increased expense associated therewith. As used herein, the phrase “electronic components having different respective thicknesses” means and includes electronic components such as transistors, capacitors, inductors, diodes, resistors, thermistors, without limitation, having different respective thicknesses. In some examples, “electronic components having different respective thicknesses” may be obtained from different electronic component manufacturers, while in some other examples, “electronic components having different respective thicknesses” may be obtained from the same electronic component manufacturer.

One of the first substrate 20 or the second substrate 30 may include an opening 39 formed therethrough. The opening 39 allows an insulative fill material 62 to be added (e.g., flowed, injected, without limitation) into interstices 61 between the first substrate 20 and the second substrate 30, as described in more detail below. The opening 39 may comprise any geometric configuration (e.g., circular, square, rectangular, irregular, without limitation) and may be dimensioned as appropriate based on the overall dimension of the apparatus 10. As shown in FIGS. 2 and 4A, a circular opening 39 is formed through the second outer conductive material 32 and the second insulative material 33 of the second substrate 30 providing communication with the interstices 61 between the first substrate 20 and the second substrate 30. In some examples, the opening 39 may have an effective diameter of from about 0.25 mm to about 1.50 mm.

The apparatus 10 formed from electronic components having different respective thicknesses includes one or more electronic components 40, 40′ (e.g., electronic components having different respective thicknesses, without limitation). As before, the electronic components 40, 40′ may include transistors, capacitors, inductors, diodes, resistors, thermistors (e.g., thermistor 49), without limitation, having different respective thicknesses. In some examples, the electronic components 40, 40′ include field-effect transistors (e.g., metal-oxide-semiconductor field-effect transistors, without limitation) having a source 46, a gate 47, and a drain 48, and in some other examples, the electronic components 40, 40′ include silicon carbide metal-oxide-semiconductor field-effect transistors, also having a source 46, a gate 47, and a drain 48. With reference again to FIGS. 1 and 2, the apparatus 10 includes several electronic components 40, 40′, 49 having different respective thicknesses (i.e., thicknesses 45, 45′ and 49′, respectively). In some examples, the electronic components 40, 40′ having different respective thicknesses may include a pair of silicon carbide metal-oxide-semiconductor field-effect transistors forming a half-bridge circuit (e.g., one high side transistor and one low side transistor, without limitation), and a thermistor 49.

A bonding material 42 (e.g., back side metallization, solder, without limitation) is provided between one or more opposing surfaces of respective ones of electronic components 40, 40′, and the thermistor 49 to facilitate electrical connectivity to other electronic components 40, 40′, and thermistor 49, or to one or more of the first inner conductive material 24 of the first substrate 20, the second inner conductive material 34 of the second substrate 30, or the steps 27, 37 (e.g., steps 27, 37a-37o), to facilitate electrical connectivity to the electronic components 40, 40′, and thermistor 49, as shown in FIGS. 1, 10 and 12. More particularly, the bonding material 42, in some examples, may include a titanium (Ti)-nickel (Ni)-silver (Ag) alloy formed thereon, and may be formed by a back side metallization process. The bonding material 42 (e.g., titanium (Ti)-nickel (Ni)-silver (Ag) alloy) may be electrically connected (e.g., sintered, without limitation) between the electronic components 40, 40′, thermistor 49, leads 52, 54 of lead frame 50, and one of the first or second inner conductive materials 24, 34 on the first substrate 20 or the second substrate 30, respectively. In other examples, the bonding material 42 may include a solder base (e.g., silver plated copper, silver plated nickel, without limitation) having a solder paste (e.g., a copper-phosphorus (CuP) solder paste, without limitation) deposited thereover. In some examples, a mass reflow process may be implemented to form electrical connections with the bonding material 42 (e.g., solder base and solder paste, without limitation) between the electronic components 40, 40′, thermistor 49, and leads 52, 54 of lead frame 50, and one of the first or second inner conductive materials 24, 34 on the first substrate 20 or the second substrate 30, respectively.

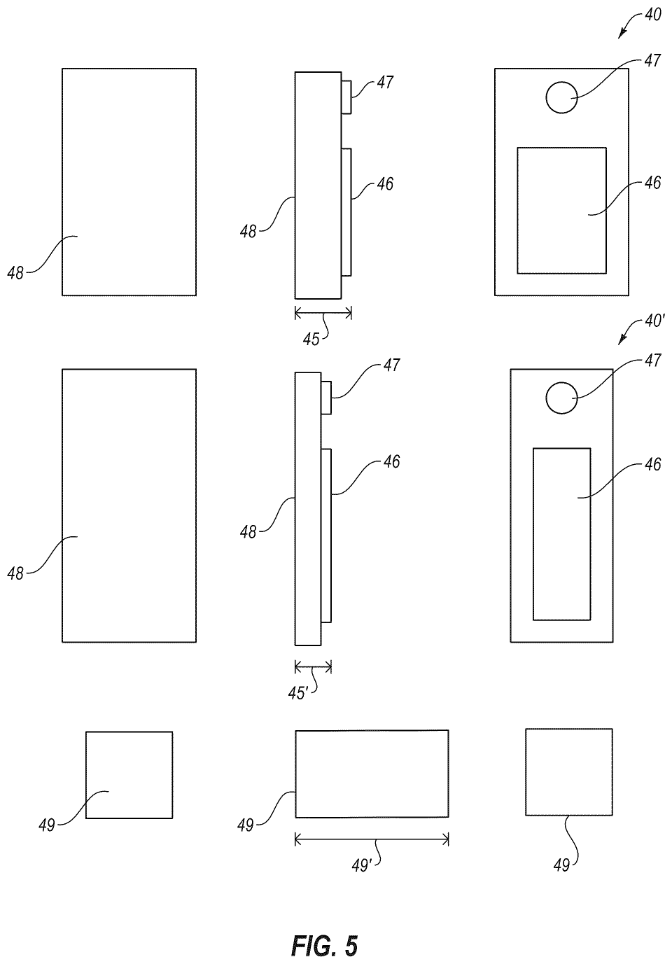

FIG. 5 presents bottom plan, side elevation, and top plan views of electronic components 40, 40′, and thermistor 49 having different respective thicknesses (e.g., electronic components having different respective thicknesses, without limitation) of an apparatus 10 (e.g., an apparatus formed from electronic components having different respective thicknesses, without limitation), in accordance with examples of the disclosure. More particularly, FIG. 5 presents bottom plan, side elevation, and top plan views of a pair of electronic components 40, 40′ (e.g., a pair of silicon carbide metal-oxide-semiconductor field-effect transistors forming a half-bridge circuit (e.g., one high side transistor and one low side transistor, without limitation)), and a thermistor 49. As shown in FIG. 5, in some examples, the thickness 45 of the electronic component 40 is greater than the thickness 45′ of the electronic component 40′, and thermistor 49 has a thermistor thickness 49′ which is greater than the thickness 45,45′ of electronic components 40, 40′, respectively. Thus, the electronic components 40, 40′ and thermistor 49 as shown in FIG. 5 are examples of electronic components having different respective thicknesses (i.e., thicknesses 45, 45′ and 49′, respectively), in accordance with examples of the disclosure.

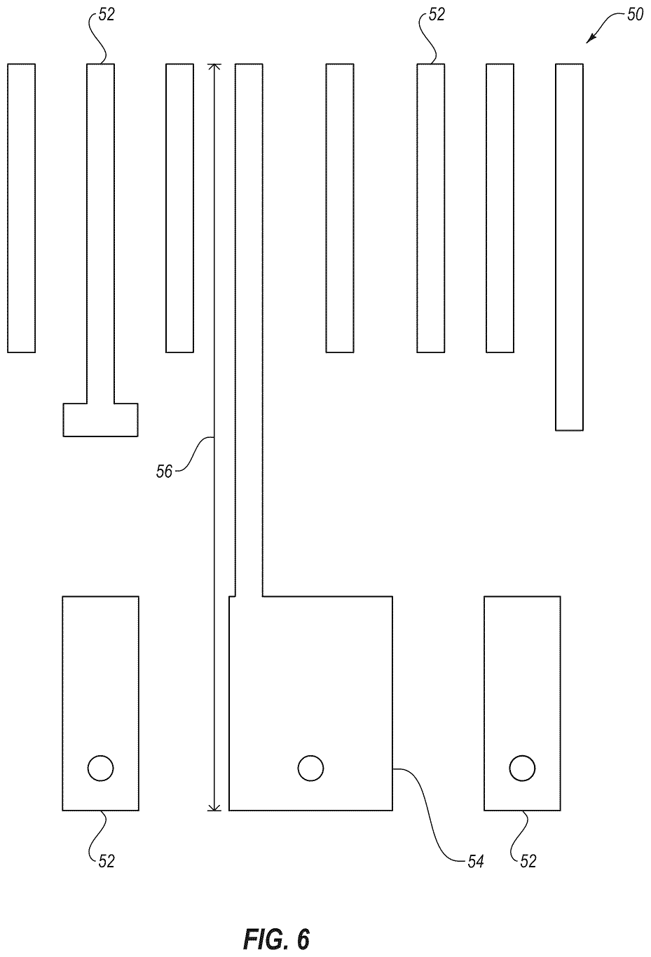

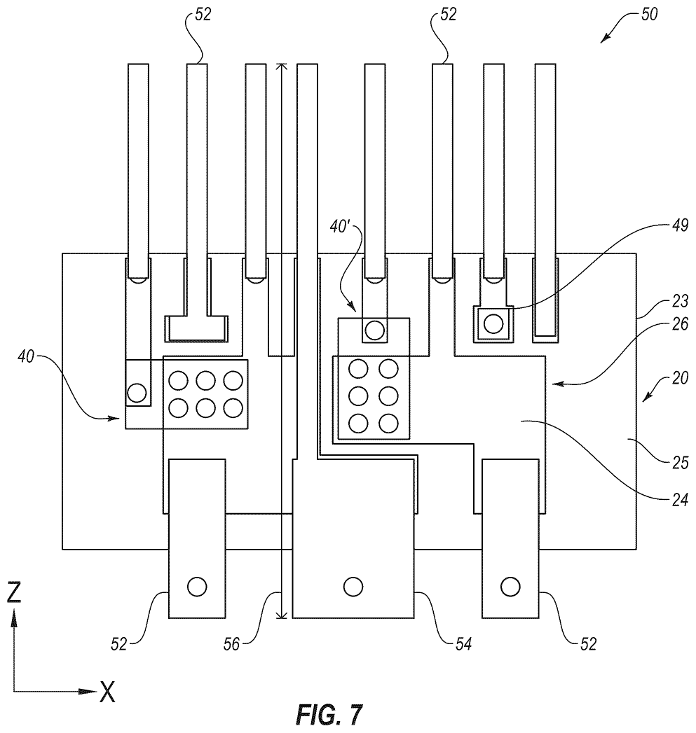

The apparatus 10 formed from electronic components having different respective thicknesses in accordance with examples of the disclosure also includes a lead frame 50. The lead frame 50 includes a number of leads 52 which may be electrically connected to electronic components 40, 40′, respectively, and thermistor 49 within the apparatus 10 to facilitate electrical connection of the apparatus 10 to external electronic devices. With reference to FIG. 6, among the various leads 52 of the lead frame 50 is an extended input/output lead 54. Extended input/output lead 54 has an extended input/output lead length 56 which extends the overall length of the lead frame 50. In some examples, the extended input/output lead length 56 is such that the extended input/output lead 54 extends continuously between opposing sidewalls of the first substrate 20 and the second substrate 30, which sidewalls are orthogonal to the respective inwardly facing surfaces 25, 35 and outwardly facing surfaces 21, 31 of the first substrate 20 and the second substrate 30, respectively, in a third direction (e.g., the Z-direction, without limitation), as may be seen best in FIGS. 7 through 9.

The leads 52, 54 of the lead frame 50 may be formed of any of a number of electrically conductive materials (e.g., metals (e.g., copper, without limitation), metal alloys (e.g., copper alloys, without limitation), or combinations thereof, without limitation). The uniform lead thickness 53 of respective leads 52, 54 of the lead frame 50 may be selected to be greater than, less than, or equal to the thickness 45, 45′ of the electronic components 40, 40′, respectively, or the thermistor thickness 49′ of thermistor 49, or any combination thereof, incorporated into the apparatus 10. In some examples, leads 52, 54 of the lead frame 50 may have a respective uniform lead thickness 53 of from about 0.1 mm to about 1.00 mm.

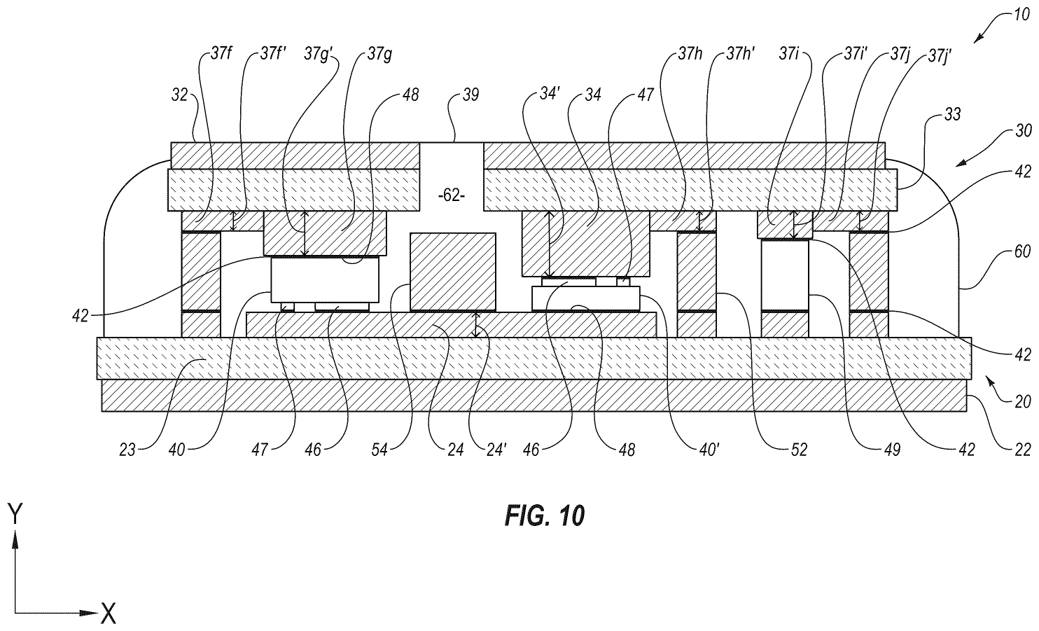

As shown in FIGS. 1 and 2, portions of the leads 52, 54 of the lead frame 50 are interspersed between the electronic components 40, 40′ and the thermistor 49 of the apparatus 10, in a first direction (e.g., the X-direction, without limitation), and between the first substrate 20 and the second substrate 30 in a second direction (e.g., the Y-direction, without limitation). More particularly, portions of some of the leads 52, 54 may be mounted between the first inner conductive material 24 of the first substrate 20 and the second inner conductive material 34 of the second substrate 30. As before, bonding material 42 (e.g., back side metallization, solder, without limitation) may be provided between one or more opposing surfaces of respective ones of the leads 52, 54 of the lead frame 50, or to one or more of the first inner conductive material 24 of the first substrate 20, the second inner conductive material 34 of the second substrate 30, or the steps 27, 37 (e.g., steps 27, 37a-37o), to facilitate electrical connectivity to the leads 52, 54 of the lead frame 50, as shown in FIGS. 1, 10 and 12. In some examples, portions of one or more of the leads 52, 54 are mounted between the first inner conductive material 24 of the first substrate 20 and steps 37 (e.g., steps 37a-37j formed in or on the second inner conductive material 34 of the second substrate 30), as shown in FIGS. 1 and 10.

In accordance with some examples, a source 46 of electronic component 40 (e.g., a high side silicon carbide metal-oxide-semiconductor field-effect transistor, without limitation) is electrically connected in series to a drain 48 of electronic component 40′ (e.g., a low side silicon carbide metal-oxide-semiconductor field-effect transistor, without limitation). More particularly, and as may be seen with reference to FIG. 1, electrical current may flow along an electrical signal path from the source 46 of electronic component 40 through the first inner conductive material 24 formed on a portion of the first inwardly facing surface 25 of the first substrate 20, through the extended input/output lead 54 of the lead frame 50, through step 37c formed in or on the second inner conductive material 34, which is formed on a portion of the second inwardly facing surface 35 on the second substrate 30, to the drain 48 of electronic component 40′, to facilitate electrical operation of the apparatus 10. Specifically, in some examples, such as is shown in FIG. 1, the extended input/output lead 54 of the lead frame 50 acts as a jumper forming an electrical connection between the first inner conductive material 24 formed on a portion of the first inwardly facing surface 25 of the first substrate 20 and the second inner conductive material 34 formed on a portion of the second inwardly facing surface 35 of the second substrate 30, via step 37c. The configuration of the electronic components 40, 40′ (e.g., silicon carbide metal-oxide-semiconductor field-effect transistors, without limitation) of the apparatus 10 as shown in FIGS. 1 and 2 may be referred to as a side-by-side source-drain configuration.

In various examples, one or more of the thicknesses 45, 45′ of the electronic components 40, 40′, respectively, the thermistor thickness 49′ of thermistor 49, the uniform lead thickness 53 of respective leads 52, 54, or the step thickness 27′, 37′ (e.g., step thickness 27′, 37a′-37o′) of steps 27, 37 (e.g., steps 27, 37a-37o), respectively, are selected to facilitate electrical connections between one or more of the electronic components 40, 40′ or the thermistor 49 having different respective thicknesses 45, 45′, 49′, respectively, and the leads 52, 54 of the lead frame 50 having uniform lead thicknesses 53, with the first inner conductive material 24 formed on a portion of the first inwardly facing surface 25 of the first substrate 20 or the second inner conductive material 34 formed on a portion of the second inwardly facing surface 35 of the second substrate 30.

Looking next to FIG. 7, presented therein is a top plan view of an apparatus 10 formed from electronic components having different respective thicknesses, with some features removed for purposes of clarity, in accordance with examples of the disclosure. As shown in FIG. 7, a pair of electronic components 40, 40′ (e.g., silicon carbide metal-oxide-semiconductor field-effect transistors, without limitation) and a thermistor 49 are mounted to portions of the first inner conductive material 24 formed on the first inwardly facing surface 25 of the first insulative material 23 of the first substrate 20 based on the first circuit pattern 26 formed thereon. In some examples, the electronic components 40, 40′ and thermistor 49 are mounted to the first inner conductive material 24 via a flip chip pick and place device, eliminating the need for wire bond electrical connections in the apparatus 10, and thereby eliminating the additional costs associated therewith. Likewise, leads 52, 54 of the lead frame 50 are also mounted to portions of the first inner conductive material 24 on the first substrate 20 in accordance with the first circuit pattern 26 formed thereon. As also shown in FIG. 7, the extended input/output lead 54 of the lead frame 50 has an extended input/output lead length 56 such that the extended input/output lead 54 extends continuously across the first substrate 20 in the third direction (e.g., continuously across the width of the first substrate 20 in the Z-direction, without limitation).

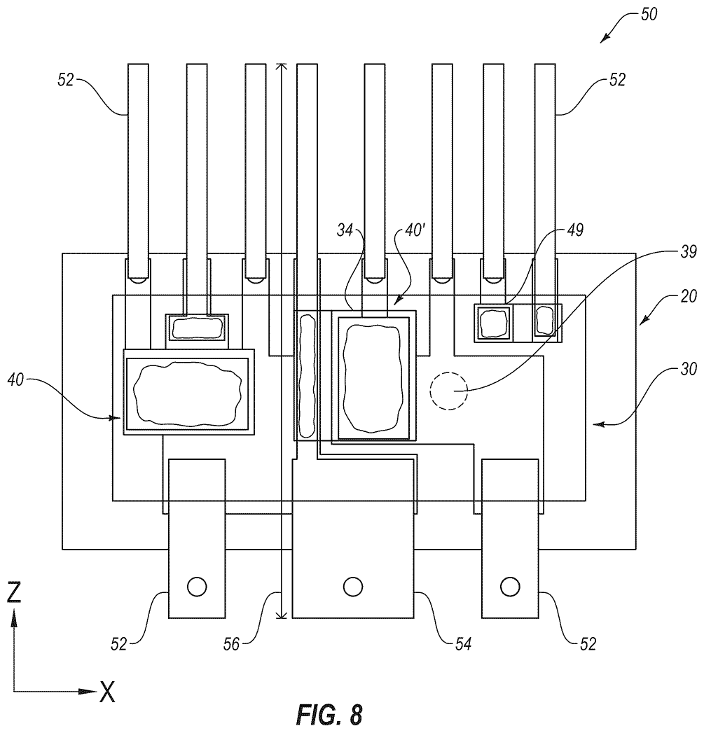

FIG. 8 is a plan view of the apparatus 10 of FIG. 7 further showing the second substrate 30 mounted to the electronic components 40, 40′, the thermistor 49, and the lead frame 50, as described hereinabove. In some examples, portions of the leads 52 of the lead frame 50, as well as portions of the extended input/output lead 54 are mounted to the steps 37 (e.g., steps 37a-37o) formed in or on the second inner conductive material 34, which is formed on a portion of the second substrate 30. As shown in FIG. 8, the extended input/output lead 54 extends continuously between opposing sidewalls of the first substrate 20 and the second substrate 30, which sidewalls are orthogonal to the respective inwardly facing surfaces 25, 35 (not shown) and outwardly facing surfaces 21, 31 (not shown) of the first substrate 20 and the second substrate 30, respectively, in the third direction (e.g., continuously across the width of the first substrate 20 and the second substrate 30 in the Z-direction, without limitation).

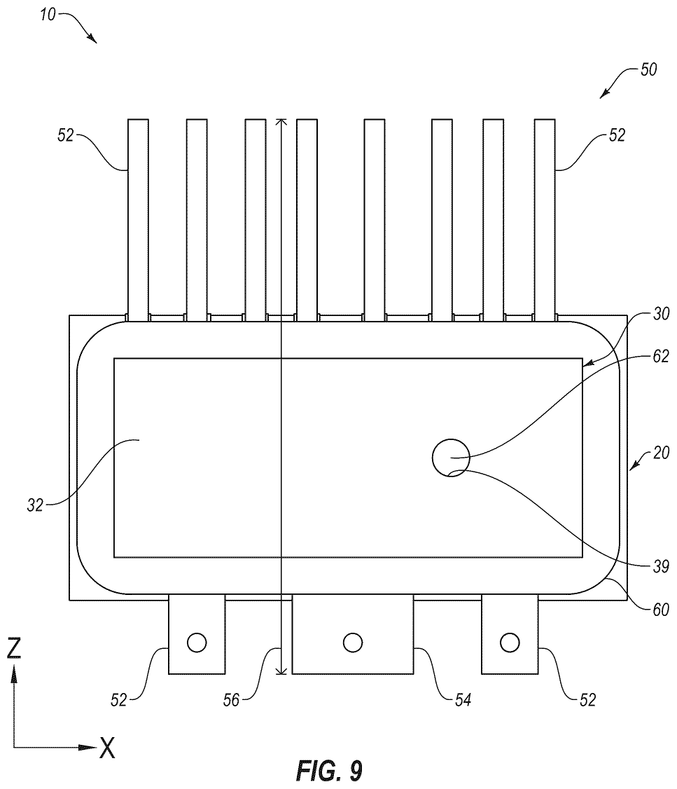

FIG. 9 presents a top plan view of the assembled apparatus 10 formed from electronic components having different respective thicknesses of FIGS. 7 and 8, in accordance with examples of the disclosure. The apparatus 10 includes a dam 60 disposed around an interface between the sidewalls of the first substrate 20 and the second substrate 30. The dam 60 is comprised of an electrically insulative material which isolates and insulates the electronic components 40, 40′, the thermistor 49, and the portions of the lead frame 50 disposed between the first substrate 20 and the second substrate 30 from the surrounding environment. The dam 60 may comprise any of a number of materials suitable for electrical and thermal insulation (e.g., polyacetals, other polyethers and epoxide resins; polycarbonates, alkyd resins, polyallyl esters and other polyesters; epoxide resins, such as, Henkel LOCTITE® Eccobond FP4451 damming material manufactured by the Loctite Division of Henkel, or equivalent, without limitation).

As further shown in FIG. 9, the opening 39 through the second substrate 30 is occupied with insulative fill material 62. The insulative fill material 62 comprises an electrically insulative and thermally conductive material which substantially occupies the interstices 61 (FIG. 2) (e.g., substantially occupies at least about 90.0 percent of the interstices, substantially occupies at least about 95.0 percent of the interstices, substantially occupies at least about 99.0 percent of the interstices, or substantially occupies at least about 99.9 percent of the interstices, without limitation) between the electronic components 40, 40′, the thermistor 49, and the portions of the leads 52, 54 of the lead frame 50 disposed between the first substrate 20 and the second substrate 30. In some examples, the insulative fill material 62 is provided through the opening 39 to occupy the interstices 61 (FIG. 2) between the pair of substrates 20, 30. The insulative fill material 62 may comprise any of a number of materials suitable for high temperature/high voltage (HT/HV) encapsulation (e.g., CEMPACK® manufactured by Heraeus Deutschland Gmbh & Co KG, without limitation).

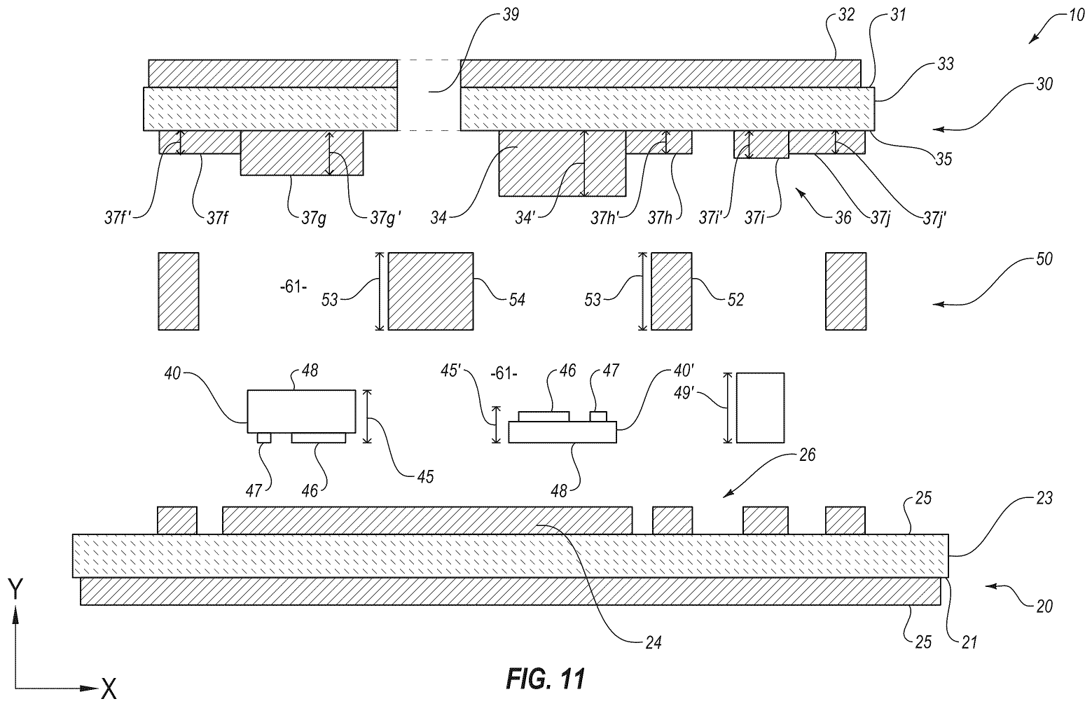

FIGS. 10 and 11 present cross-sectional and partially exploded views, respectively, of one other example of an apparatus 10 formed from electronic components having different respective thicknesses, in accordance with examples of the disclosure. It is noteworthy that, unlike the configuration as shown in FIGS. 1 and 2, the source 46 of electronic component 40 (e.g., a high side silicon carbide metal-oxide-semiconductor field-effect transistor, without limitation) is electrically connected to the drain 48 of electronic component 40′ (e.g., a low side silicon carbide metal-oxide-semiconductor field-effect transistor, without limitation) via the first inner conductive material 24 formed on a portion of the first inwardly facing surface 25 of the first substrate 20. More particularly, electrical current may flow along an electrical signal path from the source 46 of electronic component 40 through the first inner conductive material 24 formed on a portion of the first inwardly facing surface 25 of the first substrate 20 to the drain 48 of electronic component 40′, to facilitate electrical operation of the apparatus 10. This configuration of the pair of electronic components 40, 40′ (e.g., silicon carbide metal-oxide-semiconductor field-effect transistors, without limitation) may be referred to as an up-down source-drain configuration.

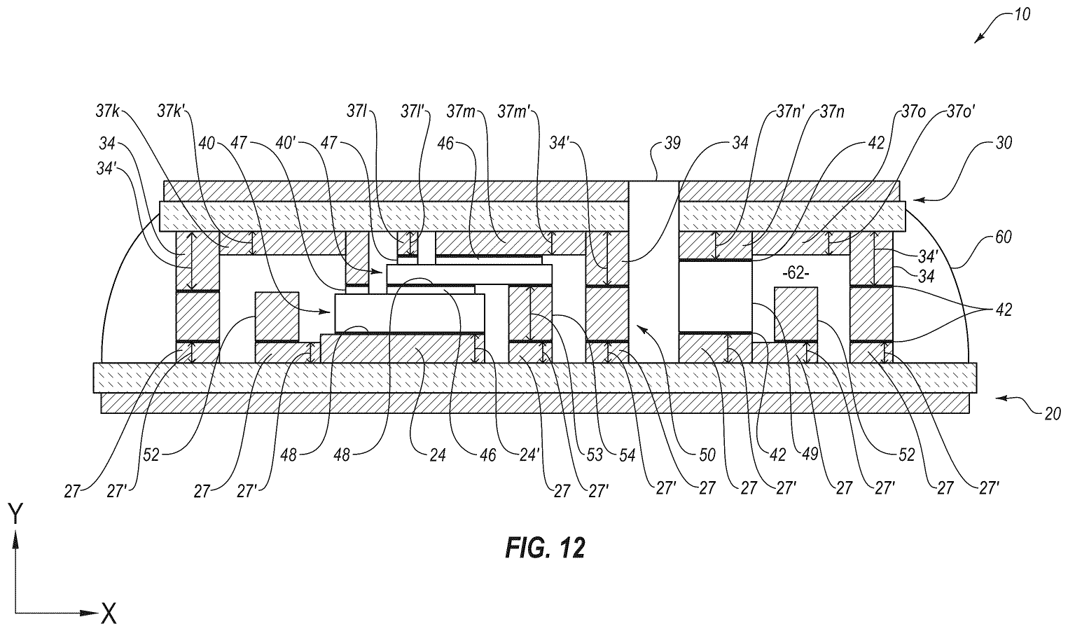

FIG. 12 presents a cross-sectional view of yet another example of an apparatus 10 formed from electronic components having different respective thicknesses, in accordance with examples of the disclosure. Unlike the configurations as shown in FIGS. 1 and 2, i.e., a side-by side source-drain configuration, or as shown in FIGS. 10 and 11, i.e., an up-down source-drain configuration, FIG. 12 presents an example of an apparatus 10 having the source 46 and drain 48 of the pair of electronic components 40, 40′ (e.g., high side and low side silicon carbide metal-oxide-semiconductor field-effect transistors, without limitation), respectively, stacked one on the other and directly electrically connected to one another through bonding material 42. More particularly, electrical current may flow along an electrical signal path from the source 46 of electronic component 40, through the bonding material 42 between the source 46 of electronic component 40 and the drain 48 of the electronic component 40′, to the drain 48 of electronic component 40′ to facilitate electrical operation of the apparatus 10, as may be seen from FIG. 12. This configuration of the pair of electronic components 40, 40′ (e.g., high side and low side silicon carbide metal-oxide-semiconductor field-effect transistors, without limitation) may be referred to as a stacked source-drain configuration. FIG. 12 is illustrative of one example of the apparatus 10 with steps 27 having uniform step thicknesses 27′ formed in or on the first inner conductive material 24 and steps 37 (e.g., steps 37l-37m) with step thicknesses 37′ (e.g., step thicknesses 37l′-37m′) formed in or on the second inner conductive material 34 to accommodate the thickness of the electronic components 40, 40′ stacked one on the other.

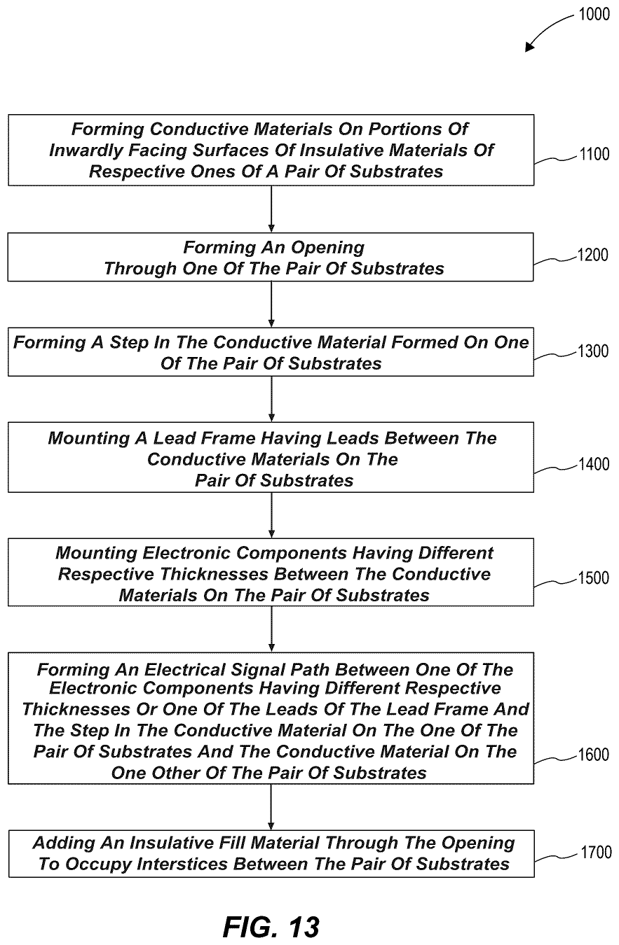

FIG. 13 presents a flowchart of one example of a method 1000 of forming an apparatus from electronic components having different respective thicknesses, in accordance with examples of the disclosure. The method 1000 of forming an apparatus from electronic components having different respective thicknesses includes forming conductive materials on portions of inwardly facing surfaces of insulative materials of respective ones of a pair of substrates, as indicated at act 1100 of FIG. 13. In some examples, the method 1000 also includes an act of removing portions of the conductive materials formed on the inwardly facing surfaces of insulative materials of respective ones of a pair of substrates, thereby exposing the underlying insulative materials of the respective substrates and forming circuit patterns from the conductive materials remaining on the underlying insulative materials of the respective ones of the pair substrates.

The method 1000 of forming an apparatus from electronic components having different respective thicknesses includes forming an opening through one of the pair of substrates, as indicated at act 1200. The method 1000 may include forming more than one opening through one or more of the pair of substrates. The method 1000 of forming an apparatus from electronic components having different respective thicknesses also includes forming a step in the conductive material formed on one of the pair of substrates, as indicated at act 1300. In some examples, the act 1300 of forming the step in the conductive material on one of the pair of substrates includes forming the step having a step thickness dimensioned to facilitate electrical connections between one of the electrical components or leads of a lead frame, with the step formed in or on the conductive material on one of the pair of substrates and the conductive material on the one other of the pair of substrates. The step in the conductive material on one of the pair of substrates includes may be formed via a subtractive process, as described hereinabove, or the step in the conductive material on one of the pair of substrates may be formed via an additive process, as also described hereinabove. In some examples, the method 1000 of forming an apparatus from electronic components having different respective thicknesses may include forming steps in the conductive materials formed on both of the pair of substrates.

With continued reference to FIG. 13, the method 1000 of forming an apparatus from electronic components having different respective thicknesses includes mounting a lead frame having leads between the conductive materials on the pair of substrates, as indicated at act 1400. In some examples, the lead frame is mounted between the conductive materials on the pair of substrates with an extended input/output lead of the lead frame extending continuously between opposing sidewalls of the first substrate and the second substrate, which sidewalls are orthogonal to the respective inwardly and outwardly facing surfaces of the first substrate and the second substrate. In other examples, mounting the lead frame having leads between the conductive materials on the pair of substrates may include mounting the leads of the lead frame between a step formed in or on the conductive material on one of the pair of substrates and the conductive material on the one other of the pair of substrates, the step having thicknesses dimensioned to facilitate electrical contact between the leads of the lead frame with the step formed in or on the conductive material on the one of the pair of substrates and the conductive material on the one other of the pair of substrates. In some other examples, mounting the lead frame having leads between the conductive materials on the pair of substrates may include mounting the leads of the lead frame between a step formed in or on the conductive material on one of the pair of substrates and a step formed in or on the conductive materials on the one other of the pair of substrates, the steps having thicknesses dimensioned to facilitate electrical contact between the leads of the lead frame with the step formed in or on the conductive material on the one of the pair of substrates and the step formed in or on the conductive material on the one other of the pair of substrates.

The method 1000 of forming an apparatus from electronic components having different respective thicknesses also includes mounting electronic components having different respective thicknesses between the conductive materials on the pair of substrates, as indicated at act 1500. As before, the phrase “electronic components having different respective thicknesses” means and includes electronic components such as transistors, capacitors, inductors, diodes, resistors, thermistors, without limitation, having different respective thicknesses. In some examples, mounting the electronic components having different respective thicknesses between the conductive materials on the pair of substrates includes mounting field-effect transistors having different respective thicknesses between the conductive materials on the pair of substrates. The field-effect transistors may be mounted in any of a number of source-drain configurations (e.g., a side-by side source-drain configuration, an up-down source-drain configuration, a stacked source-drain configuration, without limitation). In other examples, mounting the electronic components having different respective thicknesses between the conductive materials on the pair of substrates includes mounting metal-oxide-semiconductor field-effect transistors (e.g., silicon carbide metal-oxide-semiconductor field-effect transistors, without limitation) having different respective thicknesses between the pair of substrates. The metal-oxide-semiconductor field-effect transistors may be mounted in any of a number of source-drain configurations (e.g., a side-by side source-drain configuration, an up-down source-drain configuration, a stacked source-drain configuration, without limitation).

Similar to the act of mounting the lead frame having leads between the conductive materials on the pair of substrates, as at act 1400, in some examples, mounting the electronic components having different respective thicknesses between the conductive materials on the pair of substrates, as indicated at act 1500, may include mounting the electronic components having different respective thicknesses between a step formed in or on the conductive material on one of the pair of substrates and the conductive material on the one other of the pair of substrates, the step having a step thickness dimensioned to facilitate electrical contact between the electronic components having different respective thicknesses with the step formed in or on the conductive material on the one of the pair of substrates and the conductive material on the one other of the pair of substrates. In other examples, mounting the electronic components having different respective thicknesses between the conductive materials on the pair of substrates may include mounting the electronic components having different respective thicknesses between a step formed in or on the conductive material on one of the pair of substrates and a step formed in or on the conductive material on the one other of the pair of substrates, the steps having respective step thicknesses dimensioned to facilitate electrical contact between the electronic components having different respective thicknesses with the step formed in or on the conductive material on the one of the pair of substrates and the step formed in or on the conductive material on the one other of the pair of substrates.

As shown in FIG. 13, the method 1000 also includes forming an electrical signal path (e.g., electrical connection, without limitation) between the electronic components having different respective thicknesses, as indicated at act 1600. In some examples, forming the electrical signal path between the electronic components having different respective thicknesses includes forming the electrical signal path between a source of one field-effect transistor and a drain of a further field-effect transistor. In other examples, forming the electrical signal path between the electronic components having different respective thicknesses includes forming the electrical signal path between a source of one metal-oxide-semiconductor field-effect transistor and a drain of a further metal-oxide-semiconductor field-effect transistor. In other examples, forming the electrical signal path between the electronic components having different respective thicknesses includes forming the electrical signal path between one of the electronic components having different respective thicknesses and one of the leads of the lead frame.

The method 1000 of forming an apparatus from electronic components having different respective thicknesses also includes adding an insulative fill material through the opening to occupy interstices between the pair of substrates, as indicated at act 1700 in FIG. 13. In some examples, adding the insulative fill material through the opening to occupy the interstices between the pair of substrates includes adding the insulative fill material through the opening to occupy the interstices between the pair of substrates in a substantially surrounding relation to the electronic components having different respective thicknesses and portions of the leads of the lead frame disposed between the pair of substrates (e.g., substantially surrounding at least about 90.0 percent of the electronic components and the portions of the leads, substantially surrounding at least about 95.0 percent of the electronic components and the portions of the leads, substantially surrounding at least about 99.0 percent of the electronic components and the portions of the leads, or substantially surrounding at least about 99.9 percent of the electronic components and the portions of the leads, without limitation).

Additional non-limiting examples of the disclosure include:

Example 1: An apparatus, comprising: a pair of substrates; a conductive material formed on portions of respective inwardly facing surfaces of insulative materials of the pair of substrates; a step formed in or on the conductive material on one of the pair of substrates; a lead frame having leads, portions of the leads mounted between the conductive materials on the pair of substrates; electronic components having different respective thicknesses mounted between the conductive materials on the pair of substrates, one of the electronic components being thicker or thinner than one other of the electronic components or the leads of the lead frame, or the leads being thicker or thinner than one of the electronic components; the step having a step thickness dimensioned to facilitate electrical contact between a thickest one of the electronic components or the leads of the lead frame with the step formed in or on the conductive material on the one of the pair of substrates and the conductive material on the one other of the pair of substrates; and an electrical signal path between the electronic components having different respective thicknesses or the leads of the lead frame disposed in electrical contact with the step formed in or on the conductive material on the one of the pair of substrates and the conductive material on the one other of the pair of substrates.

Example 2: The apparatus according to Example 1, comprising a circuit pattern formed of the conductive material on one of the pair of substrates, the circuit pattern partially defining the electrical signal path between the electronic components having different respective thicknesses or the leads of the lead frame.

Example 3: The apparatus according to any of Examples 1 and 2, comprising an opening formed through one of the pair of substrates.

Example 4: The apparatus according to any of Examples 1 through 3, comprising an insulative fill material which substantially occupies interstices between the electronic components having different respective thicknesses and the portions of the leads of the lead frame mounted between the pair of substrates.

Example 5: The apparatus according to any of Examples 1 through 4, wherein the insulative fill material substantially surrounds the electronic components having different respective thicknesses and the portions of the leads of the lead frame mounted between the pair of substrates.

Example 6: The apparatus according to any of Examples 1 through 5, wherein the lead frame comprises an extended input/output lead extending continuously between opposing sidewalls of the pair of substrates.

Example 7: The apparatus according to any of Examples 1 through 6, wherein the electronic components having different respective thicknesses comprise field-effect transistors having different respective thicknesses and the electrical signal path is between a source of one field-effect transistor and a drain of a further field-effect transistor.

Example 8: The apparatus according to any of Examples 1 through 7, wherein the electronic components having different respective thicknesses comprise metal-oxide-semiconductor field-effect transistors having different respective thicknesses and the electrical signal path is between a source of one metal-oxide-semiconductor field-effect transistor and a drain of a further metal-oxide-semiconductor field-effect transistor.

Example 9: The apparatus according to any of Examples 1 through 8, further comprising bonding material between one or more of the electronic components having different respective thicknesses, the leads of the lead frame, the step formed in or on the conductive material of the one of the pair of substrates, or the conductive material of the one other of the pair of substrates, to facilitate electrical connectivity therebetween.

Example 10: The apparatus according to any of Examples 1 through 9, wherein the bonding material forms a portion of the electrical signal path.

Example 11: The apparatus according to any of Examples 1 through 10, wherein the bonding material comprises back side metallization or solder.

Example 12: A method, comprising: forming conductive materials on portions of inwardly facing surfaces of insulative materials of respective ones of a pair of substrates; forming an opening through one of the pair of substrates; forming a step in the conductive material on one of the pair of substrates; mounting a lead frame having leads between the conductive materials on the pair of substrates; mounting electronic components having different respective thicknesses between the conductive materials on the pair of substrates; forming an electrical signal path between one of the electronic components having different respective thicknesses or one of the leads of the lead frame and the step in the conductive material on the one of the pair of substrates and the conductive material on the one other of the pair of substrates; and adding an insulative fill material through the opening to occupy interstices between the pair of substrates.

Example 13: The method according to Example 12, wherein the forming the step in or on the conductive material on the one of the pair of substrates comprises forming the step in or on the conductive material on the one of the pair of substrates having a step thickness dimensioned to facilitate electrical contact between one of the electronic components having different respective thicknesses or one of the leads of the lead frame and the step in the conductive material on the one of the pair of substrates and the conductive material on the one other of the pair of substrates.

Example 14: The method according to any of Examples 12 and 13, wherein the mounting the lead frame having the leads between the conductive materials on the pair of substrates comprises mounting the lead frame having the leads between the conductive materials on the pair of substrates wherein one of the leads of the lead frame is mounted between the step in the conductive material on the one of the pair of substrates and the conductive material on the one other of the pair of substrates.

Example 15: The method according to any of Examples 12 through 14, wherein the mounting electronic components having different respective thicknesses between the conductive materials on the pair of substrates comprises mounting field-effect transistors having different respective thicknesses between the step in the conductive material on the one of the pair of substrates and the conductive material on the one other of the pair of substrates.

Example 16: The method according to any of Examples 12 through 15, wherein the forming the electrical signal path between the one of the electronic components having different respective thicknesses or the one of the leads of the lead frame and the step in the conductive material on the one of the pair of substrates and the conductive material on the one other of the pair of substrates comprises forming the electrical signal path between a source of one field-effect transistor and a drain of a further field-effect transistor.

Example 17: The method according to any of Examples 12 through 16, wherein the mounting electronic components having different respective thicknesses between the conductive materials on the pair of substrates comprises mounting metal-oxide-semiconductor field-effect transistors having different respective thicknesses between the step in the conductive material on the one of the pair of substrates and the conductive material on the one other of the pair of substrates.

Example 18: The method according to any of Examples 12 through 17, wherein the forming the electrical signal path between the one of the electronic components having different respective thicknesses or the one of the leads of the lead frame and the step in the conductive material on the one of the pair of substrates and the conductive material on the one other of the pair of substrates comprises forming the electrical signal path between a source of one metal-oxide-semiconductor field-effect transistor and a drain of a further metal-oxide-semiconductor field-effect transistor.

Example 19: The method according to any of Examples 12 through 18, wherein the adding the insulative fill material through the opening to occupy the interstices between the pair of substrates comprises adding the insulative fill material through the opening to occupy the interstices between the pair of substrates in a substantially surrounding relation to the electronic components having different respective thicknesses.

Example 20: An apparatus, comprising: a first substrate having a first insulative material with a first inwardly facing surface and a first inner conductive material formed on a portion of the first inwardly facing surface; a second substrate having a second insulative material with a second inwardly facing surface and a second inner conductive material formed on a portion of the second inwardly facing surface; a lead frame having leads mounted between the first substrate and the second substrate, the lead frame having an extended input/output lead extending continuously between opposing sidewalls of the first substrate and the second substrate; electronic components having different respective thicknesses mounted between the first substrate and the second substrate; a step formed in or on the first inner conductive material overlying the portion of the first inwardly facing surface of the first substrate; the step having a step thickness dimensioned to facilitate electrical contact between a thickest one of the electronic components having different respective thicknesses or of the leads of the lead frame with the step formed in or on the first inner conductive material formed on the first substrate and the second inner conductive material formed on the second substrate; and a heat dissipating outer conductive material formed on a portion of an outwardly facing surface of the first insulative material of the first substrate or the second insulative material of the second substrate.

While certain illustrative examples have been described in connection with the figures, the scope of this disclosure is not limited to those examples explicitly shown and described in this disclosure. Rather, many additions, deletions, and modifications to the examples described in this disclosure may be made to produce examples within the scope of this disclosure, such as those specifically claimed, including legal equivalents. In addition, features from one disclosed example may be combined with features of another disclosed example while still being within the scope of this disclosure.

What is claimed is:

1. An apparatus, comprising:
a pair of substrates;
a conductive material formed on portions of respective inwardly facing surfaces of insulative materials of the pair of substrates;
a step formed in or on the conductive material on one of the pair of substrates;
a lead frame having leads, portions of the leads mounted between the conductive materials on the pair of substrates;
electronic components having different respective thicknesses mounted between the conductive materials on the pair of substrates, one of the electronic components being thicker or thinner than one other of the electronic components or the leads of the lead frame, or the leads being thicker or thinner than one of the electronic components;
the step having a step thickness dimensioned to facilitate electrical contact between a thickest one of the electronic components or the leads of the lead frame with the step formed in or on the conductive material on the one of the pair of substrates and the conductive material on the one other of the pair of substrates; and
an electrical signal path between the electronic components having different respective thicknesses or the leads of the lead frame disposed in electrical contact with the step formed in or on the conductive material on the one of the pair of substrates and the conductive material on the one other of the pair of substrates.

2. The apparatus of claim 1, comprising a circuit pattern formed of the conductive material on one of the pair of substrates, the circuit pattern partially defining the electrical signal path between the electronic components having different respective thicknesses or the leads of the lead frame.

3. The apparatus of claim 1, comprising an opening formed through one of the pair of substrates.

4. The apparatus of claim 3, comprising an insulative fill material which substantially occupies interstices between the electronic components having different respective thicknesses and the portions of the leads of the lead frame mounted between the pair of substrates.

5. The apparatus of claim 4, wherein the insulative fill material substantially surrounds the electronic components having different respective thicknesses and the portions of the leads of the lead frame mounted between the pair of substrates.

6. The apparatus of claim 1, wherein the lead frame comprises an extended input/output lead extending continuously between opposing sidewalls of the pair of substrates.

7. The apparatus of claim 1, wherein the electronic components having different respective thicknesses comprise field-effect transistors having different respective thicknesses and the electrical signal path is between a source of one field-effect transistor and a drain of a further field-effect transistor.

8. The apparatus of claim 1, wherein the electronic components having different respective thicknesses comprise metal-oxide-semiconductor field-effect transistors having different respective thicknesses and the electrical signal path is between a source of one metal-oxide-semiconductor field-effect transistor and a drain of a further metal-oxide-semiconductor field-effect transistor.

9. The apparatus of claim 1, further comprising bonding material between one or more of the electronic components having different respective thicknesses, the leads of the lead frame, the step formed in or on the conductive material of the one of the pair of substrates, or the conductive material of the one other of the pair of substrates, to facilitate electrical connectivity therebetween.

10. The apparatus of claim 9, wherein the bonding material forms a portion of the electrical signal path.

11. The apparatus of claim 10, wherein the bonding material comprises back side metallization or solder.

12. A method, comprising:
forming conductive materials on portions of inwardly facing surfaces of insulative materials of respective ones of a pair of substrates;
forming an opening through one of the pair of substrates;
forming a step in the conductive material on one of the pair of substrates;
mounting a lead frame having leads between the conductive materials on the pair of substrates;
mounting electronic components having different respective thicknesses between the conductive materials on the pair of substrates;
forming an electrical signal path between one of the electronic components having different respective thicknesses or one of the leads of the lead frame and the step in the conductive material on the one of the pair of substrates and the conductive material on the one other of the pair of substrates; and
adding an insulative fill material through the opening to occupy interstices between the pair of substrates.

13. The method of claim 12, wherein the forming the step in or on the conductive material on the one of the pair of substrates comprises forming the step in or on the conductive material on the one of the pair of substrates having a step thickness dimensioned to facilitate electrical contact between one of the electronic components having different respective thicknesses or one of the leads of the lead frame and the step in the conductive material on the one of the pair of substrates and the conductive material on the one other of the pair of substrates.

14. The method of claim 12, wherein the mounting the lead frame having the leads between the conductive materials on the pair of substrates comprises mounting the lead frame having the leads between the conductive materials on the pair of substrates wherein one of the leads of the lead frame is mounted between the step in the conductive material on the one of the pair of substrates and the conductive material on the one other of the pair of substrates.

15. The method of claim 12, wherein the mounting electronic components having different respective thicknesses between the conductive materials on the pair of substrates comprises mounting field-effect transistors having different respective thicknesses between the step in the conductive material on the one of the pair of substrates and the conductive material on the one other of the pair of substrates.

16. The method of claim 15, wherein the forming the electrical signal path between the one of the electronic components having different respective thicknesses or the one of the leads of the lead frame and the step in the conductive material on the one of the pair of substrates and the conductive material on the one other of the pair of substrates comprises forming the electrical signal path between a source of one field-effect transistor and a drain of a further field-effect transistor.

17. The method of claim 12, wherein the mounting electronic components having different respective thicknesses between the conductive materials on the pair of substrates comprises mounting metal-oxide-semiconductor field-effect transistors having different respective thicknesses between the step in the conductive material on the one of the pair of substrates and the conductive material on the one other of the pair of substrates.

18. The method of claim 17, wherein the forming the electrical signal path between the one of the electronic components having different respective thicknesses or the one of the leads of the lead frame and the step in the conductive material on the one of the pair of substrates and the conductive material on the one other of the pair of substrates comprises forming the electrical signal path between a source of one metal-oxide-semiconductor field-effect transistor and a drain of a further metal-oxide-semiconductor field-effect transistor.

19. The method of claim 12, wherein the adding the insulative fill material through the opening to occupy the interstices between the pair of substrates comprises adding the insulative fill material through the opening to occupy the interstices between the pair of substrates in a substantially surrounding relation to the electronic components having different respective thicknesses.

20. An apparatus, comprising:
a first substrate having a first insulative material with a first inwardly facing surface and a first inner conductive material formed on a portion of the first inwardly facing surface;
a second substrate having a second insulative material with a second inwardly facing surface and a second inner conductive material formed on a portion of the second inwardly facing surface;
a lead frame having leads mounted between the first substrate and the second substrate, the lead frame having an extended input/output lead extending continuously between opposing sidewalls of the first substrate and the second substrate;
electronic components having different respective thicknesses mounted between the first substrate and the second substrate;
a step formed in or on the first inner conductive material overlying the portion of the first inwardly facing surface of the first substrate;
the step having a step thickness dimensioned to facilitate electrical contact between a thickest one of the electronic components having different respective thicknesses or of the leads of the lead frame with the step formed in or on the first inner conductive material formed on the first substrate and the second inner conductive material formed on the second substrate; and
a heat dissipating outer conductive material formed on a portion of an outwardly facing surface of the first insulative material of the first substrate or the second insulative material of the second substrate.
